(19) United States
(12) Patent Application Publication
(10) Pub. No.: US 2021/0395018 A1
(43) Pub. Date: Dec. 23, 2021

(54) DEVICE FOR FEEDING AND SUBSEQUENT STRIPPING OF BASE FILM CARRYING MATERIALS

(71) Applicant: TRIPLE WIN TECHNOLOGY(SHENZHEN) CO.LTD., Shenzhen (CN)

(72) Inventors: JIAN-PING ZHU, Shenzhen (CN); XIAO-SHENG YU, Shenzhen (CN)

(21) Appl. No.: 17/085,425

(22) Filed: Oct. 30, 2020

(30) Foreign Application Priority Data
Jun. 18, 2020 (CN) 202021139819.3

(51) Int. Cl. B65G 47/06; B65G 47/90; B65G 47/91; B65H 37/00; B23Q 1/03

(52) U.S. Cl. CPC B65G 47/06; B65G 47/90; B65G 47/91; B65G 2203/044; B23Q 1/03; B65G 2203/0233; B65H 37/002

(57) ABSTRACT

A device for moving film-supported materials and removing the film at a process station includes a first base, a feeding tray, a driving member, a second base, a moving member, and a laser sensor. The feeding and stripping automatically conveys a raw material assembly. A gap exists between the second base and the first base, and only raw materials are passed over the gap. The raw material assembly comprises a base layer and a number of raw materials disposed on the base layer. The gap allows the raw material disposed on a bent portion of the base layer to separate from the base layer while the base layer itself is gathered to another destination.

### FIELD

The subject matter herein generally relates to materials handling.

### BACKGROUND

Feeding devices are used in manufacturing to convey raw materials. Such feeding device may include a roller and a platform adjacent to the roller. A base film supporting raw materials is coiled around the roller. When the roller rotates, the base film uncoils from the roller and is moved, to carry the raw materials along the platform. However, the feeding device does not separate the raw materials from the base film, the raw materials need to be manually peeled away from the base film, which is time consuming. Therefore there is a need for improvement.

### BRIEF DESCRIPTION OF THE DRAWINGS

Implementations of the present technology will now be described, by way of example only, with reference to the attached figures.

FIG. 1 is a diagrammatic view of an embodiment of a feeding and stripping device.

FIG. 2 is a diagrammatic view showing connections of a driving member, a mobile assembly, and a processor of the feeding and stripping device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

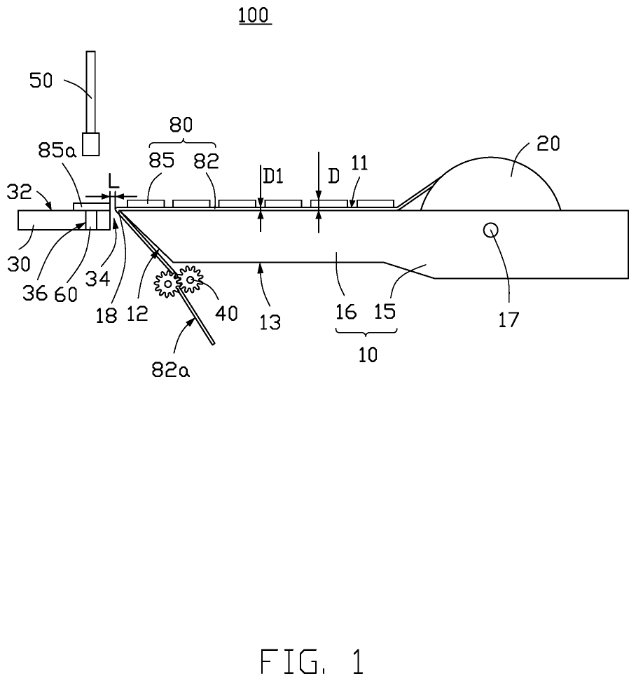

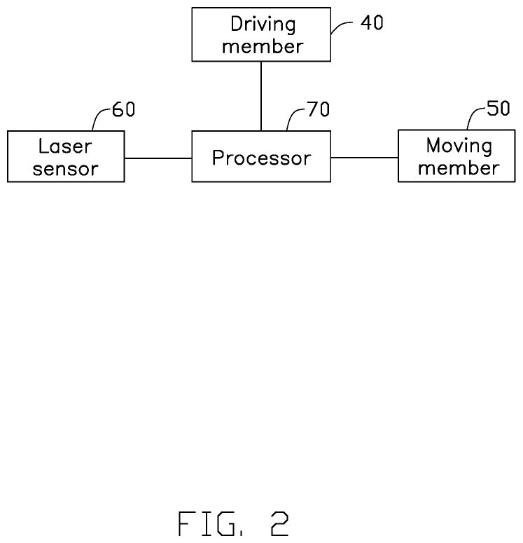

Referring to FIGS. 1 and 2, an embodiment of the present disclosure provides a feeding and stripping device 100, being a device for providing and automatically removing a film carrying materials. The feeding and stripping 100 comprises a first base 10, a feeding tray 20, a driving member 40, a second base 30, a moving member 50, a laser sensor 60, and a processor 70. The feeding and stripping 100 automatically conveys a raw material assembly 80. The raw material assembly 80 comprises a base layer 82 and a number of raw materials 85 disposed on the base layer 82. The raw materials 85 are spaced apart from each other on the base layer 82.

The first base 10 comprises a conveying surface 11, a side surface 12, and a bottom surface 13. The conveying surface 11 is disposed on the opposite side of the bottom surface 13. The side surface 12 is disposed between the conveying surface 11 and the bottom surface 13. The side surface 12 is inclined with respect to the conveying surface 11 and the bottom surface 13.

The first base 10 comprises a fixing portion 15 and an extension portion 16. The fixing portion 15 is connected to the extension portion 16. The extension portion 16 includes the side surface 12. The extension portion 16 extends from the fixing portion 15 in a direction parallel to the conveying surface 11. The extension portion 16 comprises an end (acute end 18) which resembles in section a single-sided knife edge, the acute end 18 being defined by the conveying surface 11 and the side surface 12. The angle between the conveying surface 11 and the side surface 12 is an acute angle. The acute end 18 facilitates separation of the raw material 85 from the base layer 82. In an embodiment, the angle within the acute end 18 is 45 degrees.

The fixing portion 15 supports the feeding tray 20. The raw material assembly 80 is coiled around the feeding tray 20.

The feeding tray 20 is substantially cylindrical. The fixing portion 15 further comprises a rotating shaft 17 passing through the feeding tray 20. The feeding tray 20 can rotate around the rotating shaft 17, so that the feeding tray 20 drives the raw material assembly 80 to move along the conveying surface 11. The driving member 40 is disposed on a side of the first base 10 away from the conveying surface 11. That is, the driving member 40 faces the bottom surface 13. One end portion of the base layer 82 is connected to the feeding tray 20, other end portion of the base layer 82 can be moved by the driving member 40. That is, the driving member 40 drives the raw material assembly 80 to move along the conveying surface 11 and causes a portion of the base layer 82 to be bent at the acute end 18. Thus, the raw materials 85 are separated from the base layer 82 at the acute end 18. A base layer 82a passing through the end 18 is further conveyed to the driving member 40. In one embodiment, the driving member 40 can include two gears, and the end portion of the base layer 82 passes through the two gears. The driving member 40 can also be a motor connected to the end portion of the base layer 82.

The second base 30 is disposed at a side of the extension portion 16 away from the fixing portion 15. The second base 30 is adjacent to and spaced apart from the extension portion 16.

The second base 30 comprises a supporting surface 32. In an embodiment, the supporting surface 32 and the conveying surface 11 are on a same plane. In another embodiment, the supporting surface 32 is lower than the conveying surface 11. That is, the supporting surface 32 and the conveying surface 11 are not on the same plane. The supporting surface 32 carry the raw materials 85a that pass across the acute end 18 and are separated from the base layer 82.

A gap 34 is formed between the second base 30 and the extension portion 16. The base layer 82 passes through the gap 34 and is conveyed towards the driving member 40. A width of the gap 34 is smaller than a size of the raw materials 85, thereby preventing the raw materials 85 from passing through the gap 34.

In an embodiment, along the direction perpendicular to the base layer 82, the raw material assembly 80 has a total thickness D (that is, D is a sum of a thickness of the base layer 82 and a thickness of the raw materials 85). The thickness of the base layer 82 is defined as D1. A distance between the second base 30 and the extension portion 16 (that is, the width of the gap 34) is defined as L. The D1, L, and D satisfy a formula D1≤L<D. Therefore, the gap 34 allows the base layer 82 to pass through the gap 34 while preventing the raw materials 85 from passing through. Thus, the raw materials 85 are separated from the base layer 82. The raw materials 85 after separation (marked in FIG. 1 as 85a) are then conveyed to the supporting surface 32.

The second base 30 comprises a recessed area 36. The recessed area 36 is formed by the supporting surface 32 recessing inward. The recessed area 36 is, for example, a blind hole or a through hole. The recessed area 36 can receive the laser sensor 60 therein. In an embodiment, the recessed area 36 is a through hole.

The laser sensor 60 can receive reflected light from laser beams which it emits and can receive beams reflected by an object on the supporting surface 32. Thus, the laser sensor 60 can sense the raw materials 85a on the second base 30. In an embodiment, the laser sensor 60 emits the laser beams, which are scattered in all directions after being reflected by the object (for example, the raw materials 85a). A portion of the scattered light beams is collected by the laser sensor 60.

The moving member 50 is disposed above the supporting surface 32 of the second base 30. The moving member 50 can move the separated raw materials 85a on the supporting surface 32 to a specific position when the laser sensor 60 senses the presence of the raw materials 85a. The moving member 50 may be a suction nozzle or a robot arm.

Referring to FIG. 1, the processor 70 is electrically connected to the laser sensor 60, the driving member 40, and the moving member 50. The processor 70 can control the driving member 40 and the moving member 50 to work according to signal from the laser sensor 60.

In an embodiment, when the raw materials 85a are conveyed on the feeding tray 30 and move over the laser sensor 60, the laser beams emitted by the laser sensor 60 are reflected by the raw materials 85a to the laser sensor 60. The laser sensor 60 receives the reflected signal and transmits the reflected signal to the processor 70. The processor 70 controls the driving member 40 to stop moving, and further controls the movement assembly 50 to move the raw materials 85a from the feeding tray 30. After the raw materials 85a are moved from the feeding tray 30, the laser beams emitted by the laser sensor 60 are not reflected. The laser sensor 60 does not receive the reflection signal. The processor 70 controls the moving member 50 to stop moving, and further controls the driving member 40 to move, thereby driving the raw material assembly 80 to move on. Thus, another item of raw materials 85a can be separated from the base layer 82 and then conveyed on the second base 30. The above operations are constantly repeated.

With the above configuration, the raw materials 85 are automatically separated from the base layer 82 when the base layer 82 passes over the gap 34 between the second base 30 and the feeding tray 20. The raw materials 85 are moved by the moving member 50 to the specific position, which realizes movement of raw materials by an automatic process.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A feeding and stripping, comprising:
a first base comprising a fixing portion and an extension portion, the fixing portion connected to the extension portion, the fixing portion comprising a rotating shaft, the extension portion comprising a conveying surface and a side surface, the side surface and the conveying surface cooperatively defining an end;
a feeding tray rotating around the rotating shaft, the feeding tray coils a raw material assembly around the feeding tray, the raw material assembly comprising a base layer and at least one raw material disposed on the base layer, one end portion of the base layer connected to the feeding tray;
a driving member disposed on a side of the first base away from the conveying surface, the driving member drives the base layer to move, causing a portion of the base layer to be bent at the end;
a second base disposed at a side of the extension portion away from the fixing portion, a gap formed between the second base and the extension portion, the gap allows the raw material disposed on the bent portion of the base layer to separate from the base layer;
a laser sensor disposed on the second base, and the laser sensor senses whether the raw material is located on the second base; and
a moving member moving the sensed raw material located on the second base away.

2. The feeding and stripping of claim 1, wherein along a direction perpendicular to the base layer, the raw material assembly has a total thickness defined as D, the base layer has a thickness defined as D1, a distance between the second base and the extension portion is defined as L, wherein D1, L and D satisfy a formula D1≤L<D.

3. The feeding and stripping of claim 1, wherein the second base comprises a supporting surface, a recessed area is defined on the supporting surface, the laser sensor is received in the recessed area.

4. The feeding and stripping of claim 3, wherein the recessed area is a blind hole or a through hole.

5. The feeding and stripping of claim 3, wherein the supporting surface and the conveying surface are on a same plane.

6. The feeding and stripping of claim 1, wherein an angle between the side surface and the conveying surface is an acute angle.

7. The feeding and stripping of claim 1, wherein the first base further comprises a bottom surface, the conveying surface is opposite to the bottom surface, the side surface is disposed between the conveying surface and the bottom surface, and the driving member faces the bottom surface.

8. The feeding and stripping of claim 1, wherein the driving member comprises a motor, and other end portion of the base layer is connected to the motor.

9. The feeding and stripping of claim 1, wherein the driving member comprises two gears, and other end portion of the base layer passes through the two gears.

10. The feeding and stripping of claim 1, wherein the moving member is a suction nozzle or a robot arm.
